(19) United States
(12) Patent Application Publication
(10) Pub. No.: US 2010/0033189 A1
(43) Pub. Date: Feb. 11, 2010

(54) SEMICONDUCTOR INTEGRATED CIRCUIT AND TEST METHOD USING THE SAME

(75) Inventor: Takashi Matsumoto, Chiba (JP)

Correspondence Address: SPRINKLE IP LAW GROUP, 1301 W. 25TH STREET, SUITE 408, AUSTIN, TX, 78705, US

(73) Assignee: Kabushiki Kaisha Toshiba, Tokyo (JP)

(21) Appl. No.: 12/535,130

(22) Filed: Aug. 4, 2009

(30) Foreign Application Priority Data
Aug. 5, 2008 (JP) 2008-202215

(51) Int. Cl. G01R 31/02; H03K 3/00

(52) U.S. Cl. 324/537; 327/291

(57) ABSTRACT

A semiconductor integrated circuit includes a pulse control register configured to hold an assigned code with a smaller number of bits than that of a pulse control pattern used to control an oscillation output of an oscillator, a code conversion unit configured to convert the assigned code held by the pulse control register into the pulse control pattern, and a pulse control unit configured to generate the test pulses by controlling pulses of the oscillation output of the oscillator based on the pulse control pattern resulting from the conversion by the code conversion unit.

### CROSS-REFERENCE TO RELATED APPLICATIONS

This application is based upon and claims the benefit of priority from the prior Japanese Patent Application No. 2008-202215 filed in Japan on Aug. 5, 2008; the entire contents of which are incorporated herein by reference.

### BACKGROUND OF THE INVENTION

1. Field of the Invention

The present invention relates to a semiconductor integrated circuit and a test method which uses the semiconductor integrated circuit, and more particularly, to a semiconductor integrated circuit equipped with a code conversion unit which converts assigned codes held by a pulse control register into pulse control patterns and to a test method which uses the semiconductor integrated circuit.

2. Description of the Related Art

Conventionally, a large-scale integrated circuit (LSD equipped with a sequential circuit contains a large number of flip-flop circuits. Scan tests are sometimes used for fault detection of such an LSI. The scan testing involves configuring flip-flops in a circuit as a scan flip-flop with a chain path, observing inputs and outputs, and thereby checking any fault.

Various semiconductor integrated circuits which enable such scan testing have been proposed, including a circuit proposed in Japanese Patent Application Laid-Open Publication No. 2007-327838.

Furthermore, with increases in speed of circuits to be tested, testing for delay faults (delay-fault testing) has come to be used recently. The delay-fault testing involves testing a combination circuit portion between flip-flops in a scan-designed circuit to see whether data can migrate in a predetermined delay time.

In delay-fault testing, first, necessary values are set in flip-flops using a scan chain. Next, two or more clock signals are applied quickly at a desired test frequency. Consequently, value changes produced in a first flip-flop on the first clock are captured into succeeding flip-flops on the second and subsequent clocks. By observing outputs of the flip-flops, it is possible to observe any delay fault at the test frequency between the first flip-flop and succeeding flip-flops.

Recently, very high drive frequencies have come to be used for devices in LSIs. For example, high-speed clocks with a frequency of 1 GHz are used sometimes. In this case, flip-flops need to operate at a very high speed of 1 ns (nanosecond) or less, and high speed clocks need to be used for delay-fault testing accordingly. An attempt to supply test clocks from a tester external to the LSI will cause waveform distortion, making it difficult to take measurements in the delay-fault testing. To deal with this, it is conceivable to generate test clocks using outputs from PLL circuits in the LSI. That is, test clocks are generated by selecting a clock outputted from the PLL circuits in sync with a test pattern.

Basically, such a pulse control circuit is provided for each of the PLL circuits which output clocks of different frequencies and for each of frequency-divided clocks of the outputted clocks. If clocks of different frequencies are controlled by a single pulse control circuit, flip-flops designed to operate on high-frequency clocks and flip-flops designed to operate on low-frequency clocks will have to operate on clocks of the same frequency. When operated on high-frequency clocks, flip-flops designed to operate on low-frequency clocks may not operate properly. On the other hand, when operated on low-frequency clocks, flip-flops designed to operate on high-frequency clocks cannot be used for delay-fault testing at actual speed.

A pulse control circuit disclosed in Japanese Patent Application Laid-Open Publication No. 2007-327838 stores pulse generation patterns in a register (pulse control register). The register is configured to be a shift register and values of the register are updated after each scan shift as in the case of other scan chains. For example, to control 10 pulses of a PLL circuit, 10 scan shift cycles are required.

The number of clocks in an LSI has been on the rise recently. For example, if ½ frequencies and ¼ frequencies are used as well, an LSI which has 10 PLL circuits with different frequencies requires 30 different clock frequencies. Besides, pulse control circuits, if inserted, require a pulse control register of 300 bits, which correspond to 300 flip-flops. If the 300 flip-flops are configured into a single scan chain, 300 scan shift cycles are required.

Furthermore, recent scan pattern compression techniques involve shortening the length of scan chains, thereby reducing the number of scan shift cycles. For example, when a scan chain contains 100 flip-flops, the pulse control register has 200 more flip-flops than does the scan chain.

In this way, conventional techniques have a problem in that pulse control registers need longer scan chains, requiring a longer scan shift time to store pulse generation patterns in the pulse control registers and resulting in a longer test time.

### BRIEF SUMMARY OF THE INVENTION

According to one aspect of the present invention, there is provided a semiconductor integrated circuit which supplies test pulses to a plurality of flip-flops by controlling an oscillation output of a first oscillator, including: a pulse control register configured to hold an assigned code with a smaller number of bits than that of a pulse control pattern used to control the oscillation output of the first oscillator; a code conversion unit configured to convert the assigned code held by the pulse control register into the pulse control pattern; and a pulse control unit configured to generate the test pulses by controlling the oscillation output of the first oscillator based on the pulse control pattern resulting from the conversion by the code conversion unit.

### BRIEF DESCRIPTION OF THE DRAWINGS

FIG. 1 is a block diagram showing a configuration of a semiconductor apparatus according to a first embodiment;

FIG. 2 is a block diagram showing a configuration of a semiconductor integrated circuit according to the first embodiment;

FIG. 3 is an explanatory diagram illustrating an example of pulse generation patterns and occurrence rates;

FIG. 4 is an explanatory diagram illustrating an example of settings for a code conversion table in a code conversion unit;

FIG. 5 is a block diagram showing an exemplary configuration of a combination circuit in the code conversion unit;

FIG. 6 is a flowchart illustrating an example of flow of a testing process using the semiconductor integrated circuit;

FIG. 7 is a block diagram showing a configuration of a semiconductor integrated circuit according to a second embodiment;

FIG. 8 is a block diagram showing a configuration of a semiconductor integrated circuit according to a third embodiment; and

FIG. 9 is a block diagram showing an exemplary configuration of a combination circuit in a code conversion unit.

### DETAILED DESCRIPTION OF THE INVENTION

Embodiments of the present invention will be described below with reference to the drawings.

### First Embodiment

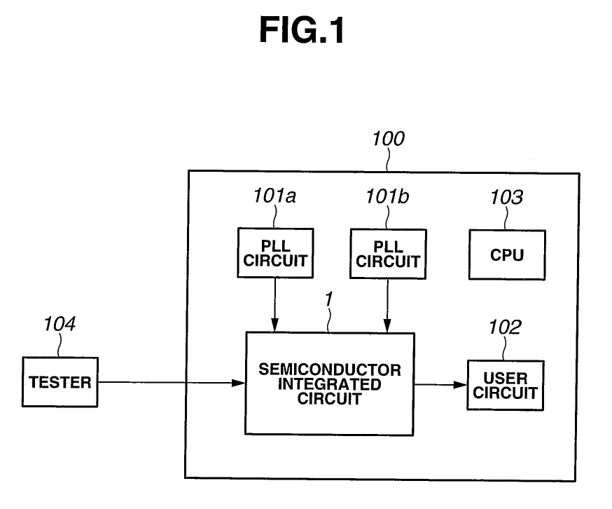

First, a configuration of a semiconductor apparatus according to a first embodiment will be described with reference to FIG. 1. FIG. 1 is a block diagram showing the configuration of the semiconductor apparatus according to the first embodiment.

As shown in FIG. 1, the semiconductor apparatus 100, which is a single-chip semiconductor apparatus, includes a semiconductor integrated circuit 1, multiple (two, in this case) PLL circuits 101a and 101b, a user circuit 102, and a CPU 103. Also, the semiconductor apparatus 100 has a tester 104 outside.

The PLL circuit 101a supplies a PLL clock signal CLK1 of a predetermined frequency to the semiconductor integrated circuit 1. The PLL circuit 101b supplies a PLL clock signal CLK2, different in frequency from the PLL clock signal CLK1 of the PLL circuit 101a, to the semiconductor integrated circuit 1.

In addition to the PLL clock signals CLK1 and CLK2, the semiconductor integrated circuit 1 is supplied with a shift clock from the tester 104. The semiconductor integrated circuit 1 generates predetermined pulses by controlling the PLL clock signals CLK1 and CLK2 using assigned codes generated based on the shift clock, as described later. The semiconductor integrated circuit 1 supplies the shift clock or the predetermined pulses thus obtained to flip-flops in the user circuit 102 or flip-flops in other circuits (not shown).

The CPU 103 controls the entire semiconductor apparatus 100.

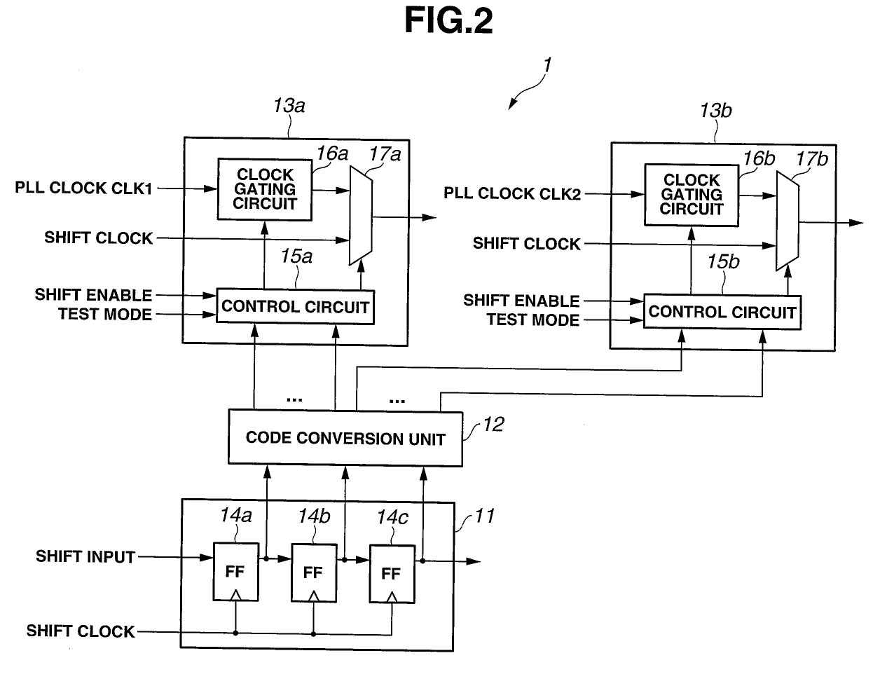

Now, a configuration of the semiconductor integrated circuit 1 will be described in detail. FIG. 2 is a block diagram showing the configuration of the semiconductor integrated circuit according to the first embodiment.

As shown in FIG. 2, the semiconductor integrated circuit 1 according to the present embodiment includes a pulse control register 11, a code conversion unit 12, and multiple (two, in this case) pulse control units 13a and 13b. Incidentally, although the semiconductor integrated circuit 1 has two pulse control units 13a and 13b, the semiconductor integrated circuit 1 may have one or more than two pulse control units. That is, it is advisable that the semiconductor integrated circuit 1 have a pulse control unit for each of different clock frequencies.

The pulse control register 11 includes three flip-flops (hereinafter abbreviated to FFs) 14a, 14b, and 14c). The three FFs 14a, 14b, and 14c are configured into a shift register, being connected in series.

The FF 14a is supplied with serial data as shift input. The FF 14a captures the serial data based on rising edges of the shift clock, holds the captured data, and outputs the data to the FF 14b. Also, the FF 14b captures the data supplied from the FF 14a based on rising edges of the shift clock, holds the captured data, and outputs the data to the FF 14c. Similarly, the FF 14c captures the data supplied from the FF 14b based on rising edges of the shift clock, holds the captured data, and outputs the data as shift output. Although the FFs 14a, 14b, and 14c capture supplied data based on rising edges of the shift clock, the FFs 14a, 14b, and 14c may capture supplied data based on falling edges of the shift clock.

Furthermore, the FFs 14a to 14c supply the held data to the code conversion unit 12. That is, the pulse control register 11 outputs the data held by the FFs 14a to 14c to the code conversion unit 12 as 3-bit assigned codes. In particular, the pulse control register 11 outputs the data held by the FF 14a, FF 14b, and FF 14c to the code conversion unit 12, as the first bit, the second bit, and the third bit, respectively.

The code conversion unit 12 stores a code conversion table which associates frequently used pulse control patterns with the 3-bit assigned codes. The code conversion unit 12 converts the 3-bit assigned codes into corresponding 20-bit pulse control patterns based on the code conversion table and outputs the resulting pulse control patterns to the pulse control units 13 a and 13b. In particular, out of the 20-bit data, the code conversion unit 12 outputs the first ten bits of the pulse control pattern, i.e., the 1st to 10th bits, to the pulse control unit 13a, and the second ten bits of the pulse control pattern, i.e., the 11th to 20th bits, to the pulse control unit 13b.

The pulse control unit 13a controls the PLL clock CLK1 for ten cycles based on the inputted ten bits of the pulse control pattern and outputs predetermined pulses obtained thereby or a shift clock to the FFs in the user circuit 102 and the like. In particular, the pulse control unit 13a controls oscillation output of the PLL clock CLK1 based on the pulse control pattern and thereby generates, for example, pulses for delay-fault testing. Similarly, the pulse control unit 13b controls the PLL clock CLK2 for ten cycles based on the inputted ten bits of the pulse control pattern and outputs predetermined pulses obtained thereby or a shift clock to the FFs in the user circuit 102 and the like.

The pulse control unit 13a includes a control circuit 15a, clock gating circuit 16a, and multiplexer (hereinafter abbreviated to MUX) 17a. On the other hand, the pulse control unit 13b includes a control circuit 15b, clock gating circuit 16b, and MUX 17b.

The control circuit 15a is supplied with sift enable and test mode signals as well as the 1st to 10th bits of the pulse control pattern described above. Based on the pulse control pattern and the sift enable and test mode signals, the control circuit 15a outputs predetermined pulse control data to the clock gating circuit 16a and outputs a switching control signal to the MUX 17a.

The clock gating circuit 16a is supplied with the PLL clock CLK1 (hereinafter simply referred to as the clock CLK) from the PLL circuit 101a. Based on the pulse control data from the control circuit 15a, the clock gating circuit 16a gates the clock CLK1 and outputs predetermined pulses obtained as a result of the gating to the MUX 17a.

The MUX 17a is supplied with the predetermined pulses from the clock gating circuit 16a and a shift clock. The MUX 17a selects the predetermined pulses or shift clock based on the switching control signal (described above) and outputs the selected predetermined pulses or shift clock to the user circuit 102 and the like.

For example, when shifting is enabled, the control circuit 15a outputs a switching control signal used to select the shift clock to the MUX 17a. When shifting is disabled, the control circuit 15a outputs pulse control data used to control the clock CLK1 to the clock gating circuit 16a, based on the test mode signal and pulse control pattern. Furthermore, the control circuit 15a outputs a switching control signal used to select output of the clock gating circuit 16a to the MUX 17a. For example, when a test mode which indicates delay-fault testing is inputted, the control circuit 15a outputs pulse control data used to generate one or more launch pulses and capture pulses to the clock gating circuit 16a.

The control circuit 15b of the pulse control unit 13b is supplied with the 11th to 20th bits (described above) of the pulse control pattern. Also, the clock gating circuit 16b is supplied by the PLL circuit 101b with the PLL clock CLK2 (hereinafter simply referred to as the clock CLK2) different in frequency from the clock CLK1. The rest of the configuration is the same as that of the pulse control unit 13a, and thus description thereof will be omitted. The clock CLK2 different in frequency from the clock CLK1 is, for example, a clock outputted from the PLL circuit 101b different from the PLL circuit 101a or a clock obtained by frequency-dividing the clock CLK1.

Incidentally, although the pulse control register 11 outputs 3-bit assigned codes to the code conversion unit 12, the pulse control register 11 may output assigned codes with a different number of bits to the code conversion unit 12. Specifically, all that is required is that the bit count of the assigned code be smaller than the product (N×M) of the number of different clock frequencies (N), i.e., the number of pulse control units, and the bit count of the pulse control pattern (M) inputted in each pulse control unit.

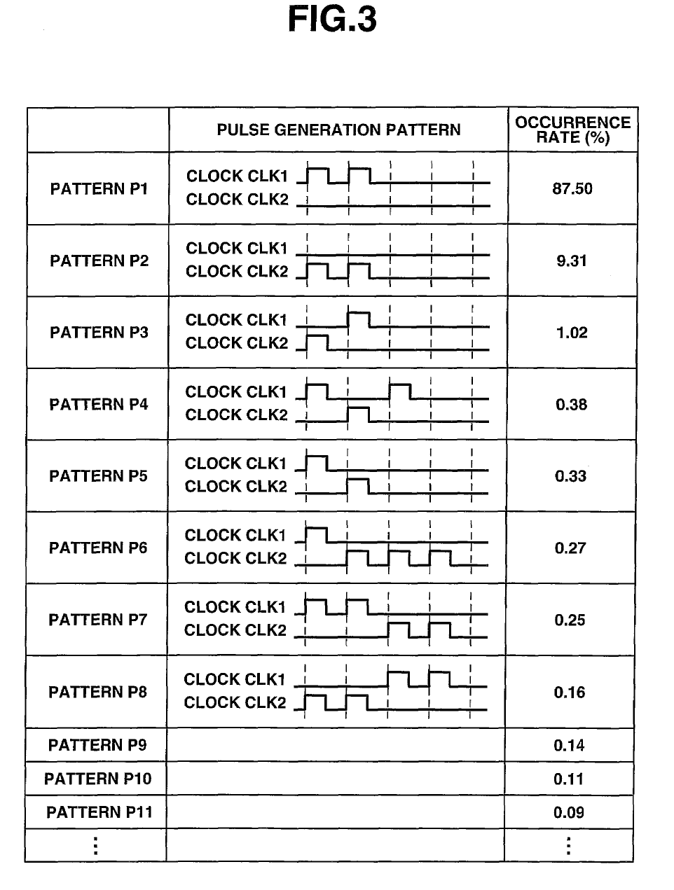

FIG. 3 is an explanatory diagram illustrating an example of pulse generation patterns and occurrence rates.

FIG. 3 shows an example of pulse generation patterns of predetermined pulses outputted from the pulse control units 13a and 13b and occurrence rates of the generated patterns. Upper eight patterns, i.e., patterns P1 to P8 make up 99.2% of a total occurrence rate. The highest occurrence rate is exhibited by pattern P1 in which two pulses of the clock CLK1 are generated. Pattern P1 is used for delay-fault testing between two FFs which operate on the clock CLK1. The next highest occurrence rate is exhibited by pattern P2 in which two pulses of the clock CLK2 are generated. Pattern P2 is used for delay-fault testing between two FFs which operate on the clock CLK2.

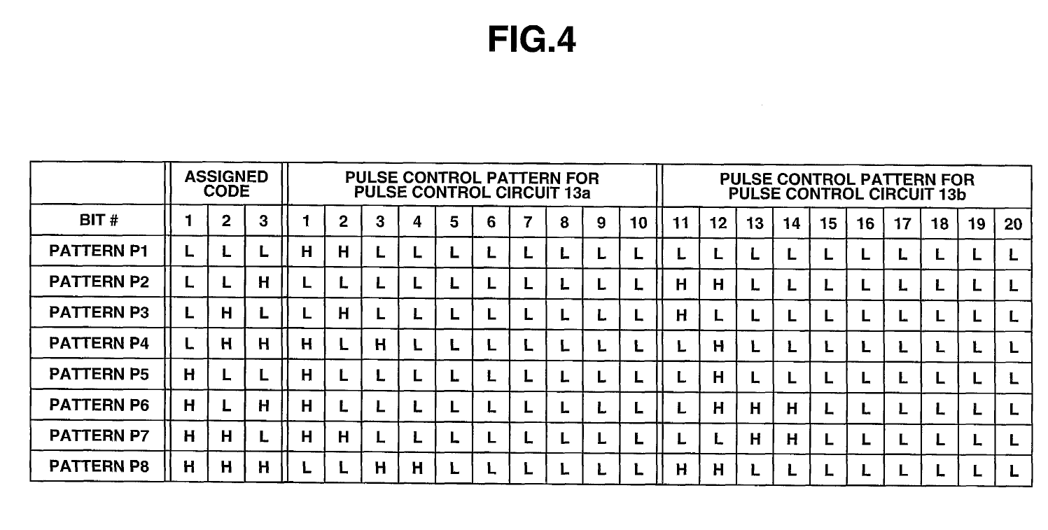

The code conversion table of the code conversion unit 12 associates the 3-bit assigned codes of the pulse control register 11 with the pulse control patterns used to generate the pulses described above. FIG. 4 is an explanatory diagram illustrating an example of settings for the code conversion table in the code conversion unit.

Also, the code conversion table assigns the pulse control patterns used to generate the pulses of the upper eight patterns shown in FIG. 3 to the 3-bit assigned codes of the pulse control register 11. As described above, the bit count of the assigned code is not limited to three bits. For example, if 4-bit assigned codes are used, pulse control patterns used to generate the pulses of the upper 16 patterns can be assigned to the 4-bit assigned codes.

For example, an assigned code whose 1st to 3rd bits are all L is converted into a pulse control pattern in which the 1st and 2nd bits are H and the 3rd to 20th bits are L. Similarly, an assigned code whose 1st and 2nd bits are L and 3rd bit is H is converted into a pules control pattern in which the 11th and 12th bits are H and the other bits are L.

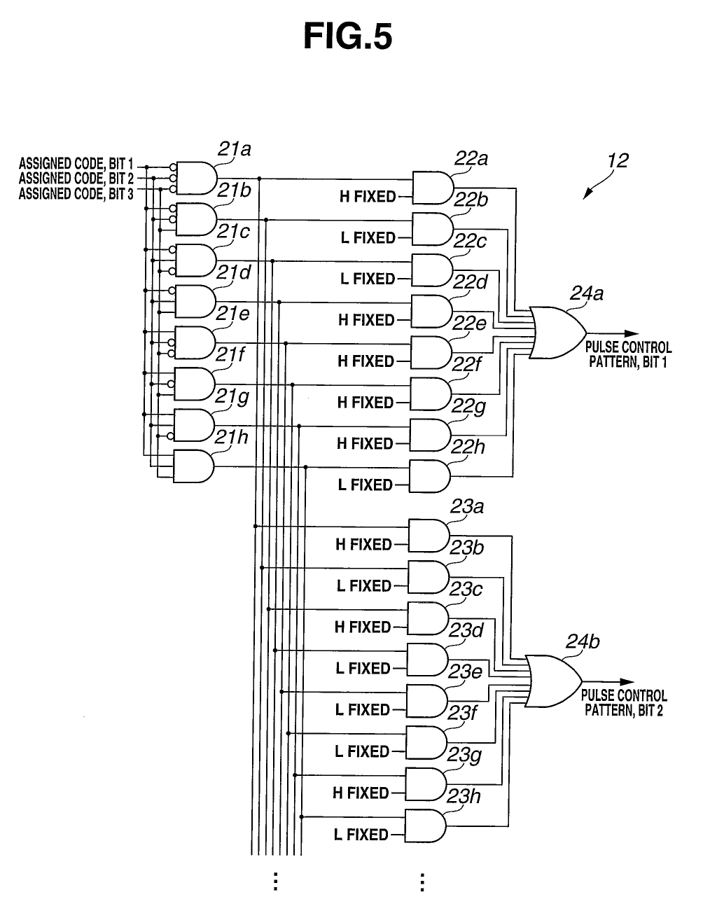

Now, a configuration of a combination circuit used to implement the code conversion table of the code conversion unit 12 will be described. FIG. 5 is a block diagram showing an exemplary configuration of a combination circuit in the code conversion unit. For ease of explanation, FIG. 5 shows that part of the circuit configuration which corresponds to the 1st and 2nd bits of the pulse control pattern.

As shown in FIG. 5, the code conversion unit 12 includes eight 3-input, 1-output AND circuits 21a to 21h; sixteen 2-input, 1-output AND circuits 22a to 22h and 23a to 23h; and two 8-input, 1-output OR circuits 24a and 24b.

A 3-bit assigned code is inputted in each of the AND circuits 21a to 21h. The AND circuit 21a is supplied with a signal with all the three bits of the assigned code inverted. Thus, when all the three bits in the assigned code are L, the AND circuit 21a outputs H to the AND circuits 22a and 23a. When the 1st bit and 2nd bit of the assigned code are L, the AND circuit 21b outputs H to the AND circuits 22b and 23b. The subsequent AND circuits behave in a similar manner, and when all the three bits in the assigned code are H, the AND circuit 21h outputs H to the AND circuits 22h and 23h.

Each of the AND circuits 22a to 22h and 23a to 23h has one of its input terminals fixed to either H or L. The AND circuits 22a to 22h output results of AND operations to the OR circuit 24a while the AND circuits 23a to 23h output results of AND operations to the OR circuit 24b.

The OR circuit 24a ORs the outputs of the AND circuits 22a to 22h and outputs a result of the OR operation as bit 1 of the pulse control pattern. Similarly, the OR circuit 24b ORs the outputs of the AND circuits 23a to 23h and outputs a result of the OR operation as bit 2 of the pulse control pattern.

For example, in pattern P3 in the code conversion table of FIG. 4, when the 1st bit of the assigned code is L, the 2nd bit is H, and the 3rd bit is L, the 1st bit of the pulse control pattern is L and the 2nd bit is H. When the 1st bit of the assigned code is L, the 2nd bit is H, and the 3rd bit is L, the result of the AND operation performed by the AND circuit 21c is H while the results of the AND operations performed by the AND circuits 21a, 21b, and 21d to 21h are L. The results of the operations performed by the AND circuits 21a to 21h are supplied to the AND circuits 22a to 22h, respectively. That is, H is supplied to the AND circuit 22c while L is supplied to the AND circuits 22a, 22b, and 22d to 22h. Consequently, the results of the AND operations performed by the AND circuits 22a, 22b, and 22d to 22h are L. Also, the result of the AND operation performed by the AND circuit 22c is L because one of the input terminals is fixed to L. Consequently, all the inputs in the OR circuit 24a are L and the result of the OR operation performed by the OR circuit 24a, i.e., the 1st bit of the pulse control pattern, is L.

Furthermore, the results of the operations performed by the AND circuits 21a to 21h are also supplied to the AND circuits 23a to 23h, respectively. That is, H is supplied to the AND circuit 23c while L is supplied to the AND circuits 23a, 23b, and 23d to 23h. Consequently, the results of the AND operations performed by the AND circuits 23a, 23b, and 23d to 23h are L. On the other hand, the result of the AND operation performed by the AND circuit 23c is H because one of the input terminals is fixed to H. Consequently, H is inputted in the OR circuit 24b from the AND circuit 23c and the result of the OR operation performed by the OR circuit 24b, i.e., the 2nd bit of the pulse control pattern, is H.

By configuring the 3rd to 20th bits of the pulse control pattern in the same manner, it is possible to implement code conversion corresponding to the code conversion table in FIG. 4. Incidentally, the circuit configuration of the code conversion unit 12 is not limited to the one shown in FIG. 5, and another circuit configuration may be used as long as the circuit carries out the code conversion shown in FIG. 4.

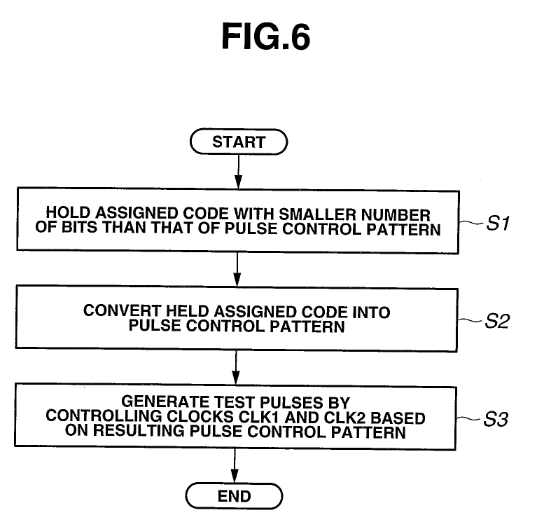

Now, a flow of a testing process using the semiconductor integrated circuit will be described. FIG. 6 is a flowchart illustrating an example of flow of a testing process using the semiconductor integrated circuit.

First, the pulse control register 11 holds an assigned code with a smaller number of bits than that of the pulse control pattern used to control the clocks CLK1 and CLK2 outputted from the PLL circuits 101a and 101b (Step S1). Next, the code conversion unit 12 converts the held assigned code into a pulse control pattern (Step S2). Finally, based on the resulting pulse control pattern, the pulse control units 13a and 13b generate test pulses by controlling the clocks CLK1 and CLK2 (Step S3). The test pulses thus generated are supplied to the FFs in the user circuit 102.

As described above, the semiconductor integrated circuit 1 is configured to have the code conversion unit 12 which converts assigned codes supplied from the pulse control register 11 into pulse control patterns. This makes it possible to reduce twenty cycles required by a conventional pulse control unit to three cycles.

Thus, the semiconductor integrated circuit according to the present embodiment can reduce the number of shifts in the pulse control register, and thereby reduce test time.

### Second Embodiment

Next, a second embodiment will be described. The semiconductor integrated circuit 1 according to the first embodiment can conduct testing using only the upper eight clock generation patterns which are used frequently. That is, the first embodiment can conduct 99.2% of the testing, but cannot conduct the remaining 0.8% of the testing. This decreases a fault detection rate. Thus, the semiconductor integrated circuit according to the present embodiment is designed to be able to conduct testing using also the remaining 0.8% of the pulse control patterns which cannot be converted by the code conversion unit.

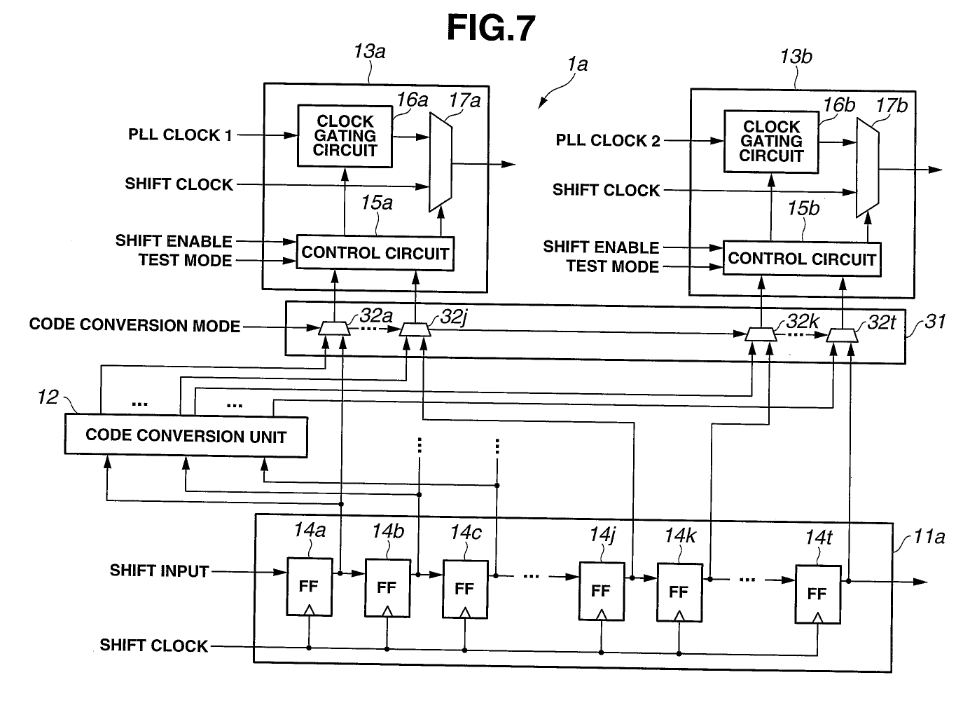

FIG. 7 is a block diagram showing a configuration of the semiconductor integrated circuit according to the second embodiment. In FIG. 7, the same components as those in FIG. 2 are denoted by the same reference numerals as those of the corresponding components in FIG. 2, and detailed description thereof will be omitted. As shown in FIG. 7, the semiconductor integrated circuit 1a according to the present embodiment includes a pulse control register 11a instead of the pulse control register 11 in FIG. 2 and additionally includes a switching unit 31.

The pulse control register 11a includes twenty flip-flops 14a to 14t. The twenty FFs 14a to 14t are configured into a shift register, being connected in series.

The switching unit 31 includes twenty MUXs 32a to 32t. Outputs from the FFs 14a to 14t are supplied to the MUXs 32a to 32t, respectively. Furthermore, 3-bit outputs from the FFs 14a, 14b, and 14c are supplied to the code conversion unit 12. The code conversion unit 12 supplies the switching unit 31 with pulse control patterns converted from the 3-bit outputs. In particular, the code conversion unit 12 supplies the 1st to 20th bits of the pulse control patterns to the MUXs 32a to 32t, respectively.

Based on a code conversion mode signal, the MUXs 32a to 32j select either the outputs of the FFs 14a to 14j, respectively, or the 1st to 10th bits, respectively, of the pulse control pattern supplied by the code conversion unit 12, and outputs the selected data to the control circuit 15a. Also, based on the code conversion mode signal, the MUXs 32k to 32t select either the outputs of the FFs 14k to 14t, respectively, or the 11th to 20th bits, respectively, of the pulse control pattern supplied by the code conversion unit 12, and outputs the selected data to the control circuit 15b. That is, regarding the remaining 0.8% of the pulse control patterns which cannot be converted by the code conversion unit, twenty bits of data held by the FFs 14a to 14t are supplied as pulse control patterns to the pulse control units 13a and 13b. In this way, the switching unit 31 selects either outputs of the pulse control register 11a or outputs of the code conversion unit 12 and supplies the selected outputs as pulse control patterns to the pulse control units 13a and 13b.

In a mode which uses the code conversion unit 12, a shift input in the pulse control register 1 la needs only to be three bits wide, which corresponds to input bit width of the code conversion unit 12. On the other hand, a pattern which is not contained in the code conversion unit 12 requires a 20-bit-wide shift input. However, such patterns have low occurrence rates, and thus do not affect the test time significantly.

In this way, the semiconductor integrated circuit 1a switches between the outputs of the pulse control register 11a and outputs of the code conversion unit 12 using the switching unit 31. This makes it possible to supply data to the pulse control units 13a and 13b by selecting the outputs of the code conversion unit 12 in the case of pulse control patterns used frequently and selecting the outputs of the pulse control register 11a in the case of pulse control patterns which cannot be converted by the code conversion unit 12.

Thus, the semiconductor integrated circuit according to the present embodiment can not only reduce the number of shifts in the pulse control register and thereby reduce test time, but also conduct testing in relation to pulse control patterns which are not contained in the code conversion unit 12.

### Third Embodiment

Next, a third embodiment will be described. The semiconductor integrated circuit 1 according to the first embodiment can conduct testing only using the upper eight clock generation patterns which are used frequently. This is because the conversion table of the code conversion unit 12 is fixed. A semiconductor integrated circuit according to the present embodiment allow the conversion table of the code conversion unit to be rewritten with any values.

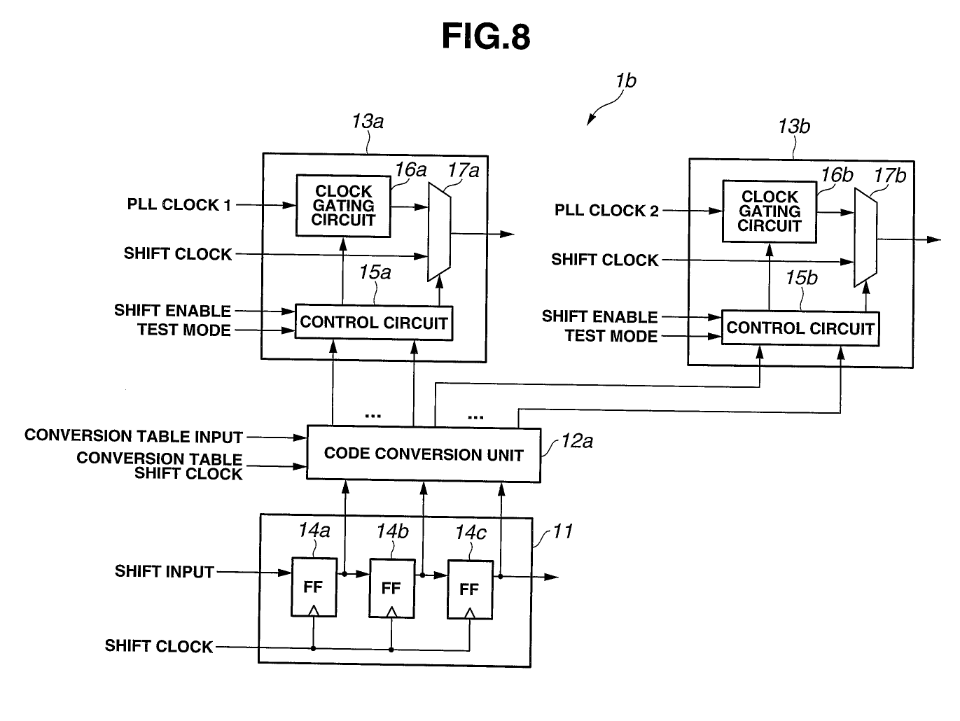

FIG. 8 is a block diagram showing a configuration of the semiconductor integrated circuit according to the third embodiment. In FIG. 8, the same components as those in FIG. 2 are denoted by the same reference numerals as the corresponding components in FIG. 2, and detailed description thereof will be omitted. As shown in FIG. 8, the semiconductor integrated circuit 1b according to the present embodiment includes a code conversion unit 12a instead of the code conversion unit 12 in FIG. 2.

To rewrite the conversion table with any values, a conversion table input and a conversion table shift clock different from a shift clock are supplied to the code conversion unit 12a.

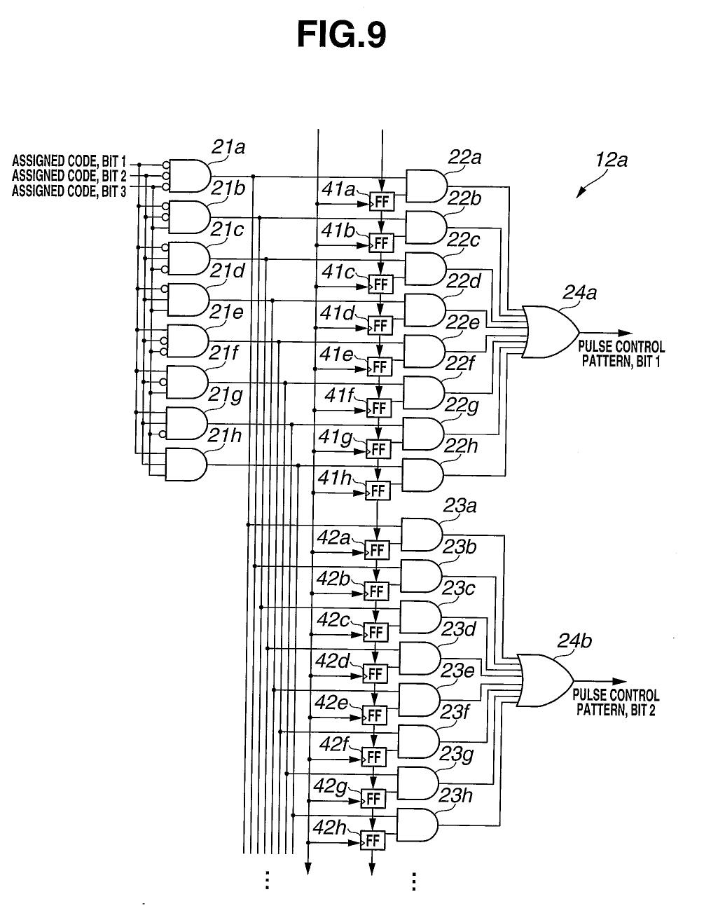

Now, a configuration of a combination circuit used to implement the code conversion table of the code conversion unit 12a will be described. FIG. 9 is a block diagram showing an exemplary configuration of a combination circuit in the code conversion unit. In FIG. 9, the same components as those in FIG. 5 are denoted by the same reference numerals as those of the corresponding components in FIG. 5, and detailed description thereof will be omitted.

In FIG. 5, each of the AND circuits 22a to 22h and 23a to 23h has one of its input terminals fixed to either H or L. In the code conversion unit 12a of FIG. 9, FFs 41a to 41h and 42a to 42h are installed upstream of the AND circuits 22a to 22h and 23a to 23h, respectively, where each FF is connected to one of the input terminals of the appropriate AND circuit. The FFs 41a to 41h and 42a to 42h are configured into a shift register, being connected in series.

Serial data is inputted in the FF 41a from the conversion table input. The FF 41a captures the inputted data on a rising edge of the conversion table shift clock and holds a value which is the captured data. The FF 41a outputs the captured data to the AND circuit 22a as well as to the FF 41b in the succeeding stage. The FF 41b captures ah inputted value on a rising edge of the conversion table shift clock and holds the captured value. In this way, each of the FFs 41a to 41h and 42a to 42h captures the value of the FF in the previous stage on a rising edge of the conversion table shift clock and holds the captured value. Consequently, the FFs 41a to 41h and 42a to 42h can hold any values. That is, the conversion table of the code conversion unit 12a can be rewritten with any values, and thus any pulse control pattern can be generated. Based on the 3-bit assigned codes from the pulse control register 11, the code conversion unit 12a outputs the pulse control pattern rewritten with the any values to the pulse control units 13a and 13b. Incidentally, the FF has been cited as the storage device which holds any values, the present embodiment is not limited to the FF, and another storage device such as a latch circuit may be used.

As described above, the semiconductor integrated circuit 1b has a shift register formed in the code conversion unit 12a. This makes it possible to capture data from the conversion table input based on the conversion table shift clock and thereby rewrite the conversion table of the code conversion unit 12a with any values.

Thus, the semiconductor integrated circuit according to the present embodiment can not only reduce the number of shifts in the pulse control register and thereby reduce test time, but also conduct testing in relation to pulse control patterns which cannot be produced by the code conversion unit.

The present invention is not limited to the embodiments described above, and various changes and alterations can be made without departing from the spirit and scope of the present invention.

What is claimed is:

1. A semiconductor integrated circuit which supplies test pulses to a plurality of flip-flops by controlling an oscillation output of a first oscillator, comprising:
a pulse control register configured to hold an assigned code with a smaller number of bits than that of a pulse control pattern used to control the oscillation output of the first oscillator;
a code conversion unit configured to convert the assigned code held by the pulse control register into the pulse control pattern; and
a pulse control unit configured to generate the test pulses by controlling the oscillation output of the first oscillator based on the pulse control pattern resulting from the conversion by the code conversion unit.

2. The semiconductor integrated circuit according to claim 1, wherein:
the pulse control register holds an assigned code with the same number of bits as that of the pulse control pattern;
the semiconductor integrated circuit further comprises a selection unit configured to select one of output of the pulse control register and output of the code conversion unit; and
the selection unit supplies selected one of the output of the pulse control register and the output of the code conversion unit to the pulse control unit as the pulse control pattern based on a switching control signal.

3. The semiconductor integrated circuit according to claim 1, wherein the code conversion unit has a storage device capable of rewriting the pulse control pattern.

4. The semiconductor integrated circuit according to claim 3, wherein the storage device is a flip-flop or a latch circuit.

5. The semiconductor integrated circuit according to claim 1, wherein the pulse control unit is provided for each of a plurality of oscillation outputs which differ in frequency from the oscillation output.

6. The semiconductor integrated circuit according to claim 1, wherein the code conversion unit has a code conversion table which converts the assigned code held by the pulse control register into the pulse control pattern.

7. The semiconductor integrated circuit according to claim 1, wherein the pulse control register includes a plurality of flip-flops connected in series.

8. The semiconductor integrated circuit according to claim 5, wherein each of the plurality of oscillation outputs which differ in frequency from the oscillation output is an oscillation output from a second oscillator different from the first oscillator or an oscillation output produced by frequency-dividing the oscillation output from the first oscillator.

9. A semiconductor integrated circuit which supplies test pulses to a plurality of flip-flops by controlling an oscillation output of a first oscillator, comprising:
a pulse control register configured to hold an assigned code with a smaller number of bits than that of a pulse control pattern used to control the oscillation output of the first oscillator;
a code conversion unit configured to convert the assigned code held by the pulse control register into the pulse control pattern; and
a gating circuit configured to generate the test pulses by gating the oscillation output of the first oscillator based on the pulse control pattern resulting from the conversion by the code conversion unit.

10. The semiconductor integrated circuit according to claim 9, wherein:
the pulse control register holds an assigned code with the same number of bits as that of the pulse control pattern;
the semiconductor integrated circuit further comprises a selection unit configured to select one of output of the pulse control register and output of the code conversion unit; and
the selection unit supplies selected one of the output of the pulse control register and the output of the code conversion unit to the gating circuit as the pulse control pattern based on a switching control signal.

11. The semiconductor integrated circuit according to claim 9, wherein the code conversion unit has a storage device capable of rewriting the pulse control pattern.

12. The semiconductor integrated circuit according to claim 11, wherein the storage device is a flip-flop or a latch circuit.

13. The semiconductor integrated circuit according to claim 9, wherein the gating circuit is provided for each of a plurality of oscillation outputs which differ in frequency from the oscillation output.

14. The semiconductor integrated circuit according to claim 9, wherein the code conversion unit has a code conversion table which converts the assigned code held by the pulse control register into the pulse control pattern.

15. The semiconductor integrated circuit according to claim 9, wherein the pulse control register includes a plurality of flip-flops connected in series.

16. The semiconductor integrated circuit according to claim 13, wherein each of the plurality of oscillation outputs which differ in frequency from the oscillation output is an oscillation output from a second oscillator different from the first oscillator or an oscillation output produced by frequency-dividing the oscillation output from the first oscillator.

17. A test method using a semiconductor integrated circuit which supplies test pulses to a plurality of flip-flops by controlling an oscillation output of a first oscillator, the test method comprising:
holding an assigned code with a smaller number of bits than that of a pulse control pattern used to control the oscillation output of the first oscillator;
converting the held assigned code into the pulse control pattern; and
generating the test pulses by controlling the oscillation output of the first oscillator based on the pulse control pattern resulting from the conversion.

18. The test method using a semiconductor integrated circuit according to claim 17, the test method further comprising:
holding an assigned code with the same number of bits as that of the pulse control pattern; and
selecting one of the assigned code with the same number of bits as that of the pulse control pattern and the pulse control pattern resulting from the conversion based on a switching control signal and providing whichever has been selected as the pulse control pattern.

19. The test method using a semiconductor integrated circuit according to claim 17, wherein a storage device capable of rewriting the pulse control pattern is provided.

20. The test method using a semiconductor integrated circuit according to claim 19, wherein the storage device is a flip-flop or a latch circuit
